(19) United States
(12) Patent Application Publication
(10) Pub. No.: US 2025/0072194 A1
(43) Pub. Date: Feb. 27, 2025

(54) LIGHT-EMITTING ELEMENT AND METHOD OF PRODUCING LIGHT-EMITTING ELEMENT

(71) Applicant: DOWA Electronics Materials Co., Ltd., Tokyo (JP)

(72) Inventors: Masahito MIYASHITA, Akita-shi (JP); Yasuhiro WATANABE, Akita-shi (JP); Haruka HIRAYAMA, Akita-shi (JP)

(73) Assignee: DOWA Electronics Materials Co., Ltd., Tokyo (JP)

(21) Appl. No.: 18/810,506

(22) Filed: Aug. 21, 2024

(30) Foreign Application Priority Data
Aug. 22, 2023 (JP) 2023-135029

(51) Int. Cl. H01L 33/62; H01L 33/00; H01L 33/12

(52) U.S. Cl. CPC H01L 33/62; H01L 33/007; H01L 33/12

(57) ABSTRACT

Provided is a light-emitting element having excellent close adherence between a protective film and a semiconductor layer. The light-emitting element is a flip chip-type light-emitting element including a buffer layer formed on a main surface of a substrate, an n-type AlGaN layer formed on the buffer layer, and a light-emitting layer and a p-type AlGaN layer formed in order on at least part of the n-type AlGaN layer. An exposed surface of the substrate is present at an end section on the main surface of the substrate. In a cross-section of the light-emitting element, the exposed surface is inclined at an acute angle θs of 45° or less relative to a horizontal line of an interface between the substrate and the buffer layer.

### TECHNICAL FIELD

The present disclosure relates to GaN-based and AlGaN-based light-emitting elements and a method of producing a light-emitting element.

### BACKGROUND

GaN-based and AlGaN-based group III nitride semiconductors are used in light-emitting elements for ultraviolet wavelength regions of 200 nm to 280 nm (UVC), 280 nm to 320 nm (UVB), and 320 nm to 400 nm (UVA).

For example, Patent Literature (PTL) 1 describes causing inclination, relative to a plane parallel to a light-emitting layer, of at least one surface among an end surface of the light-emitting layer and an outer surface of an insulating film that is in contact with the end surface of the light-emitting layer such that an angle formed by a normal to the surface and the plane parallel to the light-emitting layer is not less than a specific angle. The reason for this is that when the end surface of a light-emitting layer in a light-emitting element is inclined relative to a plane parallel to the light-emitting layer, reflection at the end surface enables extraction of reflected light of light that could not originally be extracted from a light extraction surface.

Conventionally, in the case of a light-emitting element that is of a flip chip type, etching for street region formation is performed after etching has been performed to expose an n-type semiconductor layer for n-type electrode formation.

PTL 2 describes a process order in which a mask is formed for exposing an n-type semiconductor layer, reactive ion etching (RIE) is performed using SiCl₄ gas and Cl₂ gas, and then, after mask removal, a mask of a pattern such as to obtain a specific chip size is applied and etching is performed by RIE until a sapphire substrate is exposed so as to form a street region.

### CITATION LIST

### Patent Literature

PTL 1: JP2003-347589A
PTL 2: JP2000-4066A

### SUMMARY

In recent years, there has been demand for further improvement of light-emission efficiency of light-emitting elements and also for improvement of reliability of light-emitting elements. In a light-emitting element, it is often the case that an insulating film formed of SiO₂, SiN, or the like is provided as a protective film completely covering a group III nitride semiconductor in order to suppress leakage current and also protect the element from moisture, etc. The occurrence of peeling, cracking, or the like in such a protective film may result in deterioration of close adherence between the protective film and a semiconductor layer and loss of reliability of the element.

In PTL 1, a configuration in which an exposed surface of a substrate is present at an end section on a main surface of the substrate and in which this exposed surface is covered by a protective film is illustrated. However, no consideration is given to peeling of the protective film and inclination of the exposed surface of the substrate in PTL 1. A protective film is also not considered in PTL 2.

In the present disclosure, the object is to obtain a light-emitting element and a method of producing a light-emitting element with which peeling, cracking, or the like of a protective film is unlikely to occur.

As a result of diligent and extensive research aimed at achieving the object described above, the inventor and others found that the angle at which a protective film is in contact with a semiconductor layer at a plane where a substrate and the semiconductor layer are in contact is important for preventing peeling, cracking, or the like of the protective film. In addition, the inventor and others found that in order to provide such an angle, it is appropriate to perform etching in order to expose an n-type semiconductor layer for n-type electrode formation after etching has been performed up to the substrate for street region formation.

Specifically, the essence of the present disclosure is as follows.

(1) A light-emitting element of a flip chip type comprising: a buffer layer formed on a main surface of a substrate; an n-type AlGaN layer formed on the buffer layer; and a light-emitting layer and a p-type AlGaN layer formed in order on at least part of the n-type AlGaN layer, wherein an exposed surface of the substrate is present at an end section on the main surface of the substrate, and in a cross-section of the light-emitting element, the exposed surface has an inclined section that is inclined at an acute angle θs of 45° or less relative to a horizontal line of an interface between the substrate and the buffer layer.

(2) The light-emitting element according to the foregoing (1), wherein the acute angle θs satisfies 2°<θs<30°.

(3) The light-emitting element according to the foregoing (1) or (2), wherein when an angle formed in the buffer layer by the interface and a side surface of the buffer layer is taken to be θb, θs<30°≤θb≤75°, and θs+(180°−θb) is 120° or more.

(4) The light-emitting element according to any one of the foregoing (1) to (3), wherein an end section where an exposed surface of the n-type AlGaN layer and a side surface of the n-type AlGaN layer meet is formed with a rounded shape.

(5) The light-emitting element according to any one of the foregoing (1) to (4), wherein the substrate includes a sapphire substrate, and the buffer layer includes at least an undoped AlN buffer layer.

(6) The light-emitting element according to any one of the foregoing (1) to (5), further comprising a protective film that covers at least respective side surfaces of the p-type AlGaN layer, the light-emitting layer, the n-type AlGaN layer, and the buffer layer and that covers at least the inclined section.

(7) A method of producing a light-emitting element comprising: a first step including a step of forming a buffer layer on a main surface of a substrate, a step of forming an n-type AlGaN layer on the buffer layer, and a step of forming a light-emitting layer and a p-type AlGaN layer in order on the n-type AlGaN layer; a second step of etching at least part of the p-type AlGaN layer, the light-emitting layer, the n-type AlGaN layer, and the buffer layer up to the substrate to form a street region at the substrate; and a third step of exposing part of the n-type AlGaN layer by etching the p-type AlGaN layer and the light-emitting layer once again after the second step, wherein in a cross-section after the third step, the street region of the substrate has an inclined section that is inclined at an acute angle θs of 45° or less relative to a horizontal line of an interface between the substrate and the buffer layer.

(8) The method of producing a light-emitting element according to the foregoing (7), further comprising a fourth step of forming a protective film on at least respective side surfaces of the p-type AlGaN layer, the light-emitting layer, the n-type AlGaN layer, and the buffer layer that have been formed through etching in the second step and the third step and forming a protective film on at least the inclined section of the street region of the substrate.

According to the present disclosure, it is possible to provide a light-emitting element and a method of producing a light-emitting element with which peeling, cracking, or the like of a protective film is unlikely to occur.

### BRIEF DESCRIPTION OF THE DRAWINGS

In the accompanying drawings:

FIG. 1 is a cross-sectional schematic view for describing an angle θs and an angle θb in the present disclosure;

FIG. 2 is a cross-sectional schematic view illustrating the structure of a light-emitting element according to the present disclosure;

FIG. 3A is a first process diagram for describing a method of producing a light-emitting element according to the present disclosure;

FIG. 3B is a second process diagram for describing a method of producing a light-emitting element according to the present disclosure;

FIG. 3C is a third process diagram for describing a method of producing a light-emitting element according to the present disclosure;

FIG. 4A is a first process diagram for describing a production method in a case in which a light-emitting element similar to in the present disclosure is produced by a conventional production method;

FIG. 4B is a second process diagram for describing a production method in a case in which a light-emitting element similar to in the present disclosure is produced by a conventional production method;

FIG. 4C is a third process diagram for describing a production method in a case in which a light-emitting element similar to in the present disclosure is produced by a conventional production method;

FIG. 5 presents a cross-sectional SEM image of a light-emitting element according to Example 1; and

FIG. 6 presents a cross-sectional SEM image of a light-emitting element according to Example 2.

### DETAILED DESCRIPTION

The following points are described in advance, prior to description of an embodiment in accordance with the present disclosure.

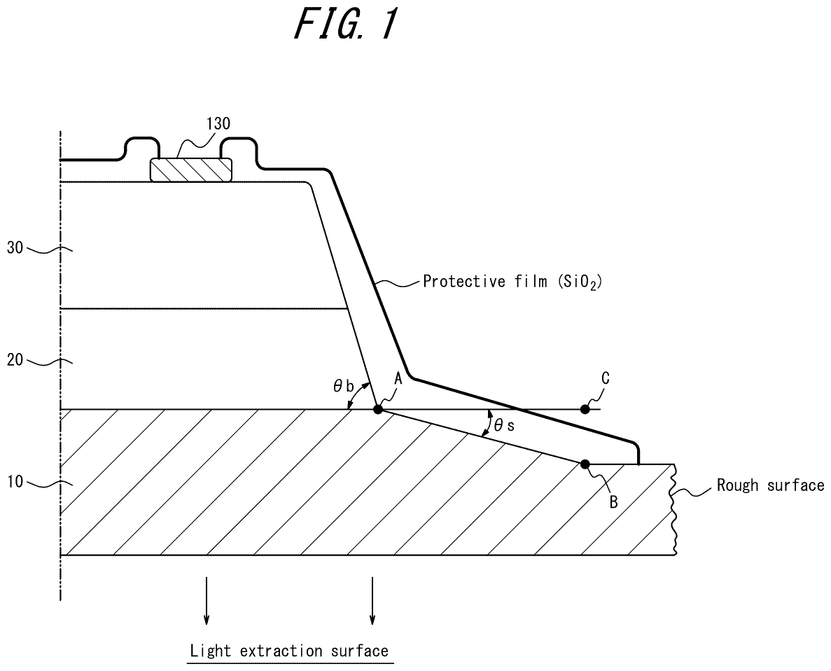

FIG. 1 is part of a cross-sectional view of a light-emitting element in a present embodiment. A buffer layer 20 and an n-type AlGaN layer 30 are stacked in order on a substrate 10, and an n-type electrode 130 is formed on part of the n-type AlGaN layer 30. With the exception of around the center of an upper surface of the n-type electrode 130 and around a planned separation location of the substrate 10, a protective film is formed on an exposed surface of the substrate 10, a side surface of the buffer layer 20, a side surface of the n-type AlGaN layer 30, an upper surface of the n-type AlGaN layer 30, and a side surface and an upper surface periphery of the n-type electrode 130. A rear surface side of the substrate 10 is a light extraction surface.

<Angle θs>

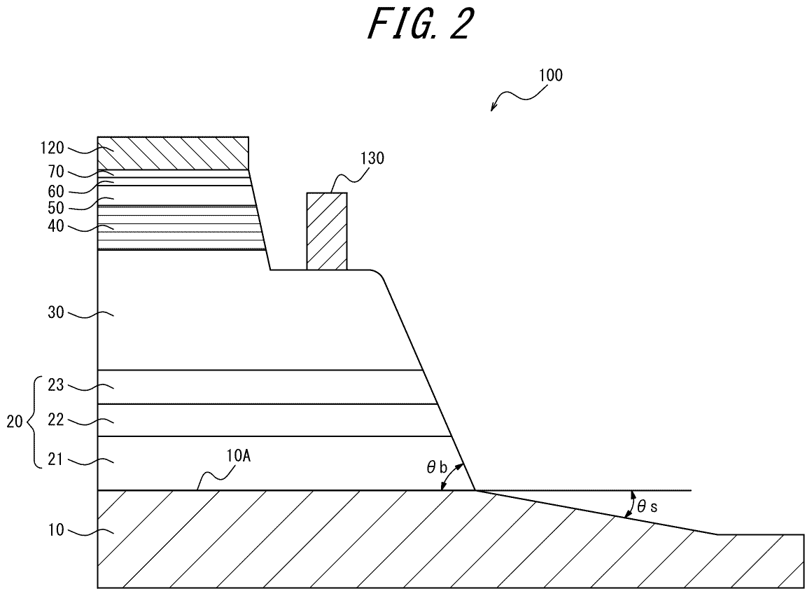

An angle θs corresponds to an angle BAC when, in FIG. 1, a contact point between the exposed substrate 10 and the buffer layer 20 is taken to be A, an arbitrary point of an inclined section on the exposed substrate 10 (exposed surface) is taken to be B, and an arbitrary point outside of the light-emitting element on a horizontal line of an interface between the substrate 10 and the buffer layer 20 is taken to be C. The exposed surface of the substrate 10 is inclined toward the light extraction surface-side relative to the horizontal line of the interface between the substrate 10 and the buffer layer 20 in FIG. 1. In a case in which the inclination of the exposed surface on the substrate 10 is a straight line, the point B is an arbitrary point on the straight line. In a case in which the inclination of the exposed surface on the substrate 10 is a polyline or a curve, the point B is set as a position where a straight line that comes into contact with the exposed surface of the substrate 10 can be drawn with the contact point A as a starting point. When the substrate 10 is referred to as “exposed”, this is inclusive of a state in which the substrate 10 is covered by the protective film and expresses a state in which a semiconductor layer is not present between the protective film and the substrate 10. Note that illustration of the protective film is omitted from FIG. 2 onwards. In the present specification, the section that is inclined in FIG. 1 (section between A and B in FIG. 1) is referred to as an inclined section.

<Angle θb>

An angle θb is an angle that is formed by the interface between the substrate 10 and the buffer layer 20 and a side surface of the buffer layer 20 in FIG. 1. In a case in which the side surface of the buffer layer 20 is a straight line, the angle θb is an angle formed with that straight line. In a case in which the side surface of the buffer layer 20 is a polyline or a curve, the angle θb is taken to be an angle formed with a straight line that is drawn such as to come into contact with the side surface of the buffer layer 20 with the contact point A as a starting point.

Evaluation of the above-described inclination angles (θs and θb) in the present embodiment is performed by using an FIB (focused ion beam) or the like with respect to the light-emitting element to perform cross-section formation, acquiring a cross-sectional SEM (scanning electron microscope) image, and measuring angles in that image. For example, in the present embodiment, a ×20,000 cross-sectional SEM image is acquired, a horizontal line of an interface between the substrate 10 and the buffer layer 20 in the image is drawn, a straight line contacting with an exposed surface of the substrate 10 and a straight line contacting with a side surface of the buffer layer 20 are drawn with the contact point A as a starting point, and the angles formed by these lines are measured.

Evaluation of close adherence of the protective film in the present embodiment is performed by acquiring a cross-sectional SEM image and checking for the presence of cracks, voids, and protective film peeling in the acquired image. For example, in the present embodiment, a check is made in proximity to the contact point A in a ×20,000 cross-sectional SEM image.

“AlGaN” referred to in the present embodiment means AlₐGa₁₋ₐN having an Al composition ratio of a. The value of the Al composition ratio a of AlGaN in the present embodiment is identified from wavelengths observed in photoluminescence measurement performed with respect to the surface of each layer after that layer has been grown. The Al composition ratio a is not less than 0 and not more than 1 unless otherwise specified. Examples of methods by which the Al composition ratio can be identified from a cross-section of a light-emitting element include EDS (energy dispersive X-ray spectroscopy).

The main surface of a semiconductor layer referred to in the present embodiment means a surface that is most suitable for crystal growth among crystal orientations.

Dopant concentrations referred to in the present disclosure are values measured by SIMS (secondary ion mass spectrometry). In the present specification, a case in which a specific impurity such as Si or Mg is not intentionally added and that does not function electrically as a p-type or an n-type is referred to as an “i” type or as “undoped”. An undoped layer may contain impurities that are unavoidably mixed in during the production process. Specifically, a case in which the dopant density is small and is close to the lower limit of detection by SIMS (for example, less than 4×10¹⁶/cm³) is treated as “undoped” in the present specification.

Evaluation of crystallinity in the present embodiment is taken to be the value of the full width at half maximum (arcsec) of an X-ray rocking curve obtained using an X-ray diffractometer. The full width at half maximum may be determined through automatic calculation by application software accompanying the X-ray diffractometer.

The following describes an embodiment of the present disclosure.

### (Light-Emitting Element)

The following describes a light-emitting element obtained through the present embodiment. The light-emitting element according to the present embodiment is a flip chip-type light-emitting element 100 that includes a buffer layer 20 formed on a main surface 10A of a substrate 10, an n-type AlGaN layer 30 formed on the buffer layer 20, and a light-emitting layer 40 and a p-type AlGaN layer 50 formed in order on at least part of the n-type AlGaN layer 30.

As illustrated in FIG. 2, the buffer layer 20 preferably includes an AlN buffer layer 21 and may include a first buffer layer 22 and/or a second buffer layer 23 that are formed of AlGaN. A p-type cladding layer 60 and/or a p-type contact layer 70 may be formed in order on the p-type AlGaN layer 50.

A feature of the light-emitting element 100 is that the substrate 10 has an exposed surface at an end section on the main surface 10A and that this exposed surface has an inclined section that is inclined at an acute angle θs of 45° or less relative to a horizontal line of an interface between the substrate 10 and the buffer layer 20. Moreover, the substrate 10 is preferably a sapphire substrate. It may be the case that the entire exposed surface is the inclined section or that part of the exposed surface is not inclined. In a case in which part of the exposed surface is not inclined, the part that is not inclined may be horizontal.

The angle θs preferably satisfies 2°<θs<30°, and more preferably satisfies 5°≤θs≤15°. The angle θb preferably satisfies 30°≤θb≤75°, and more preferably satisfies 45°≤θb≤65°. With regards to a relationship between the angle θs and the angle θb, it is preferable that θs+(180°−θb) is 120° or more, and more preferably 125° or more.

In the light-emitting element 100, it is preferable that an end section where an exposed surface on a main surface of the n-type AlGaN layer 30 and a side surface of the n-type AlGaN layer 30, which is inclined at the angle θb, meet is formed with a rounded shape.

In a situation in which a protective film protecting the light-emitting element 100 has been formed, it is preferable that peeling, cracking, or the like of the protective film does not occur. The protective film is preferably formed such as to cover respective side surfaces of the buffer layer 20, the n-type AlGaN layer 30, the light-emitting layer 40, the p-type AlGaN layer 50, the p-type cladding layer 60, and the p-type contact layer 70 and the inclined section of the substrate 10. The protective film is preferably not formed on at least central sections (bonding regions) of upper surfaces of a p-side electrode and an n-type electrode, but may cover the peripheries of the p-side electrode and the n-type electrode.

By forming a protective film in the light-emitting element 100 in accordance with the present disclosure, it is possible to obtain a light-emitting element with which peeling, cracking, or the like of the protective film is unlikely to occur. The following provides a more detailed description of each configuration through description of an embodiment of a production method for obtaining the light-emitting element 100 and of each step in this production method.

### (Method of Producing Light-Emitting Element)

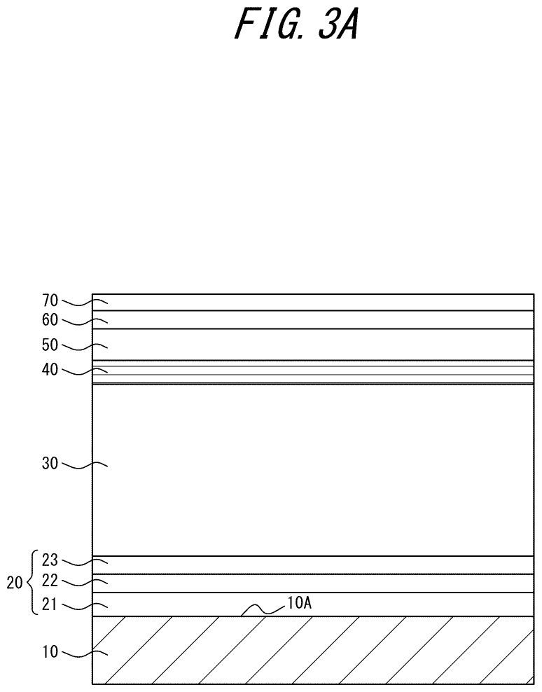

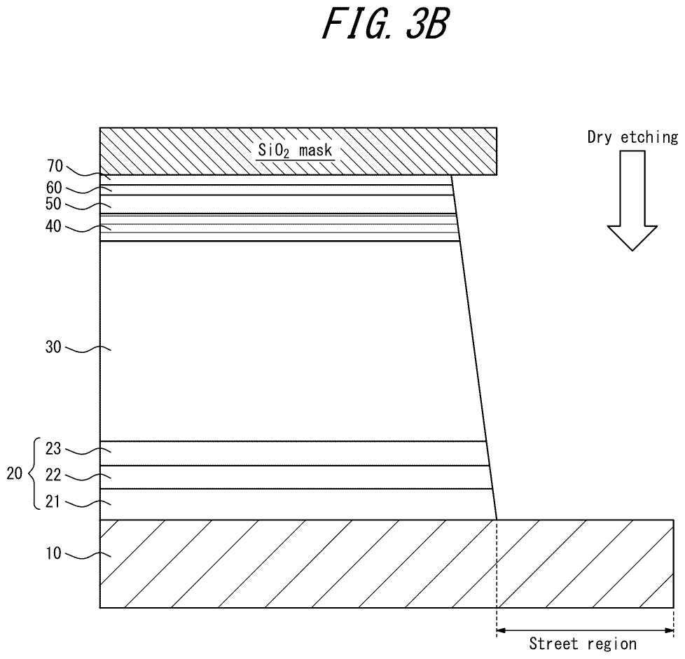

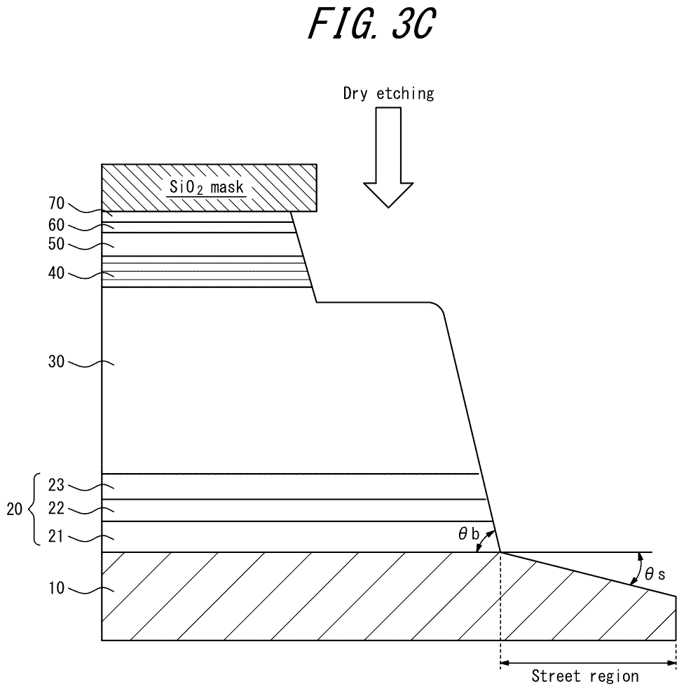

FIGS. 3A to 3C are process diagrams of a production method for the light-emitting element 100 described above. As illustrated in FIGS. 3A to 3C, a method of producing the light-emitting element 100 in accordance with the present disclosure includes a first step (FIG. 3A) of forming each semiconductor layer through epitaxial growth on the main surface 10A of the substrate 10, a second step (FIG. 3B) of dry etching the semiconductor layers formed in the first step up to the substrate 10 so as to form a street region, and a third step (FIG. 3C) of performing dry etching once again so as to expose a main surface of the n-type AlGaN layer 30.

### First Step

In the first step, the substrate 10 is first prepared. A substrate that has been produced according to a standard method can be used as the substrate 10. The substrate 10 preferably includes a sapphire substrate.

The buffer layer 20, the n-type AlGaN layer 30, the light-emitting layer 40, and the p-type AlGaN layer 50 are formed in order on the substrate 10 so as to form the light-emitting element 100 on the substrate 10 (FIG. 3A). The following provides a brief description of each of the constituent layers of the light-emitting element 100.

First, the buffer layer 20 is epitaxially grown on the substrate 10. The buffer layer 20 can be formed by MOCVD (metal organic chemical vapor deposition), for example. The buffer layer 20 preferably includes an AlN buffer layer 21 and may further have a first buffer layer 22 and/or a second buffer layer 23 formed of AlGaN stacked in order on the AlN buffer layer 21. The thickness of the AlN buffer layer 21 is preferably not less than 0.3 μm and not more than 0.7 μm. The AlN buffer layer 21 is preferably undoped. The Al composition ratio of AlGaN may be the same or different in the first buffer layer 22 and the second buffer layer 23. In a case in which the first buffer layer 22 and the second buffer layer 23 have different Al composition ratios, the Al composition ratio of the first buffer layer 22 is preferably higher. The thickness of the first buffer layer 22 is preferably not less than 10 nm and not more than 50 nm, and the thickness of the second buffer layer 23 is preferably not less than 200 nm and not more than 2,000 nm. Moreover, the first buffer layer 22 and the second buffer layer 23 are preferably undoped.

Next, the n-type AlGaN layer 30 is stacked on the buffer layer 20. The thickness of the n-type AlGaN layer 30 should be sufficiently thick for supplying carriers and is preferably not less than 300 nm and not more than 3,000 nm, for example. An element with which the n-type AlGaN layer 30 is doped may be Si or the like.

Next, the light-emitting layer 40 is stacked on the n-type AlGaN layer 30. The light-emitting layer 40 is preferably a layer that includes a layer formed of AlGaN. The light-emitting layer 40 may have a single layer structure or may have a multiple quantum well structure in which a plurality of barrier layers and well layers are stacked alternately. The drawings for the present embodiment illustrate a multiple quantum well structure as an example. Although not illustrated, an undoped AlGaN layer of not less than 1 nm and not more than 5 nm in thickness may be further provided in contact with the light-emitting layer 40.

Next, the p-type AlGaN layer 50 is stacked on the light-emitting layer 40. A p-type cladding layer 60 may be further provided on the p-type AlGaN layer 50. It is preferable that the p-type cladding layer 60 is formed of p-type AlGaN and has a lower Al composition ratio than the p-type AlGaN layer 50. An element with which the p-type AlGaN layer 50 and the p-type cladding layer 60 are doped may be Mg or the like. A p-type contact layer 70 formed of p-type AlGaN that is for facilitating electrode formation may be provided on the p-type cladding layer 60. The p-type contact layer is preferably formed of a p-type GaN layer, and the doped element may be Mg or the like.

### Second Step

In the second step, a CVD (chemical vapor deposition) apparatus is first used to form an insulating film over the entire surface of the p-type contact layer 70. Examples of insulating films that can be used include SiO₂, SiN, and the like. In the present embodiment, an SiO₂ layer is described as the insulating film. This SiO₂ layer can fulfill a role as a mask during subsequently described RIE.

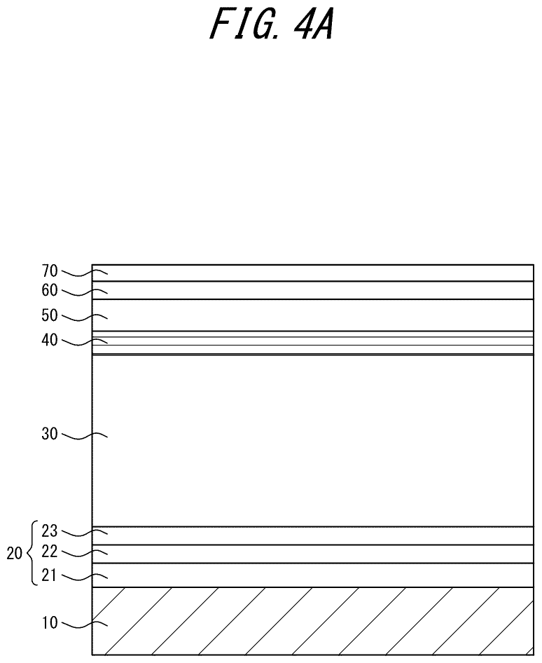

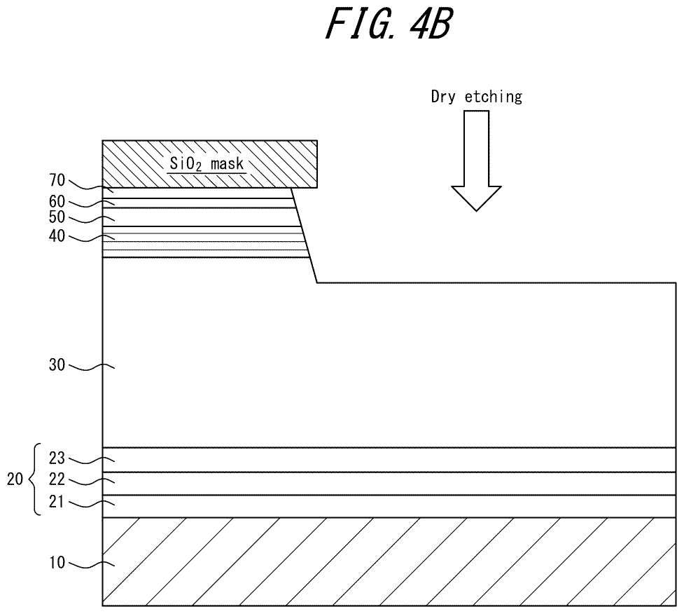

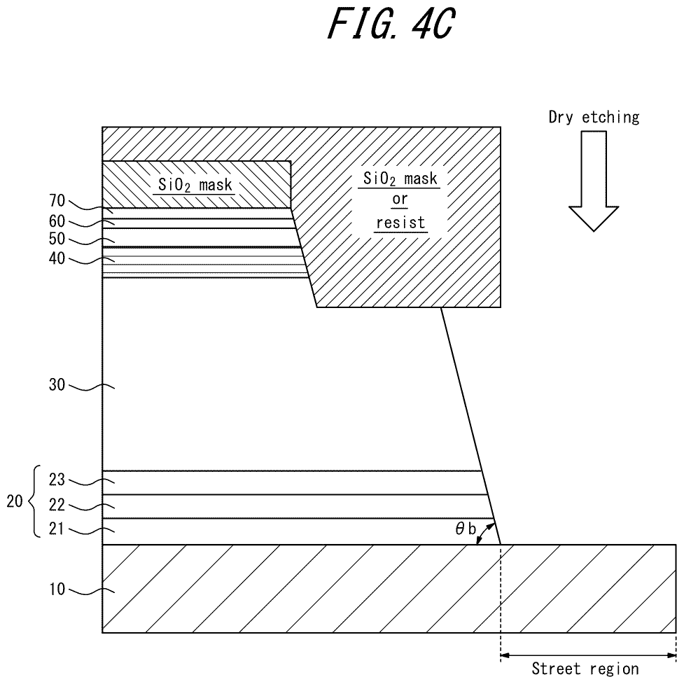

Next, it is preferable that mask pattern formation by a resist is used with respect to the SiO₂ layer on the p-type contact layer 70 so as to etch and remove the SiO₂ layer in a well-shaped region (street region; street width range: 50 μm to 150 μm) having a sufficient street width such that a planned separation line by subsequent laser scribing is positioned around the center. The resist is preferably subsequently removed. Thereafter, an RIE apparatus is used to etch each group III nitride layer in the street region that is not covered by the SiO₂ layer as illustrated in FIG. 3B so as to expose the substrate 10 in the street region. FIG. 3B is a schematic view at the end of etching. FIG. 3B schematically illustrates the appearance of formation of an inclination at the side surfaces of the group III nitride layers and the formation of an eave at the mask of the SiO₂ layer as a result of side etching occurring together with depth direction etching of the group III nitride layers. Note that vertical and horizontal dimensions in the drawings do not illustrate the ratio of an actual product and are exaggerated in order to facilitate understanding. The same also applies to FIG. 3C, FIG. 4B, and FIG. 4C.

### Third Step

In the third step, a main surface of the n-type AlGaN layer 30 is exposed as illustrated in FIG. 3C for subsequent formation of an n-type electrode. First, it is preferable that mask pattern formation by a resist is used so as to retain the SiO₂ layer on the p-type contact layer 70 in a region (light-emission region) where the p-type semiconductor layers (p-type contact layer 70, p-type cladding layer 60, and p-type AlGaN layer 50) and the light-emitting layer 40 are to be retained and to remove the SiO₂ layer by etching other than in that region. Thereafter, an RIE apparatus is used to expose the n-type AlGaN layer 30 in a range that is not covered by the SiO₂ layer as illustrated in FIG. 3C. As a result of the third step being performed after the second step, the substrate 10 in the street region that has been exposed during the street formation step is subjected to etching for a second time.

In the street formation step of the second step, it is necessary to etch each of the p-type contact layer 70, the p-type cladding layer 60, the p-type AlGaN layer 50, the light-emitting layer 40, the n-type AlGaN layer 30, and the buffer layer 20. Since this requires a deep etching depth of thousands of nanometers or more, it is preferable to use a combination of gases that results in a high AlGaN etching rate. For example, a combination of Cl₂ gas and BCl₃ gas can be used. The depth of the group III nitride layers that is etched by this etching may be set in accordance with the thickness of the light-emitting element that has been epitaxially grown.

On the other hand, in the step of exposing the n-type AlGaN layer 30 in the third step, the p-type contact layer 70, the p-type cladding layer 60, the p-type AlGaN layer 50, and the light-emitting layer 40 should be etched. Since the etching depth is on the scale of tens to hundreds of nanometers, it is preferable to use a combination of gases that results in a lower AlGaN etching rate than in the street formation step. For example, a combination of Cl₂ gas and SiCl₄ gas can be used. As a result, formation of the angle θs progresses at the already exposed substrate 10 that is distant from the mask, and thus an inclined section is formed in the street region. The depth of the group III nitride that is etched by this etching may be set in accordance with the thickness of the light-emitting element that has been epitaxially grown. It is preferable that etching is caused to progress to a depth at which the n-type AlGaN layer 30 is partially etched at the light-emitting layer-side thereof so as to ensure that the surface of the n-type AlGaN layer 30 is exposed.

Moreover, in order that an end section where an exposed surface of the main surface of the n-type AlGaN layer 30 and a side surface of the n-type AlGaN layer 30 meet is formed with a rounded shape, it is preferable that etching conditions are optimized such that there is a low aspect ratio through the RIE apparatus in the second step and the third step and that the etching conditions of the SiO₂ in the third step are also optimized.

After part of the n-type AlGaN layer 30 has been exposed as described above, the SiO₂ layer on the p-type contact layer 70 may be removed by etching. The SiO₂ layer is preferably at least removed at a position where a subsequently described p-side electrode 120 is to be formed.

The p-side electrode 120 is preferably formed on the p-type contact layer 70. A commonly known electrode that can be used with the p-type contact layer 70 is preferably selected as the p-side electrode 120, and a reflective electrode is preferable as the p-side electrode 120. For example, a first metal (Ni) and a second metal (Rh) or a conductive metal nitride can be used as the p-side electrode 120.

In addition, an n-type electrode 130 is preferably formed on part of the n-type AlGaN layer 30 that has been exposed. A commonly known electrode may be selected as the n-type electrode 130. For example, a first metal (Ti) and a second metal (Al) or a conductive metal nitride can be used as the n-type electrode 130.

Stacking of the p-side electrode 120 and the n-type electrode 130 can be performed by a commonly known film growth method such as sputtering, for example. Moreover, it is preferable that a lift-off method using a resist is adopted in electrode pattern formation of the p-side electrode 120 and the n-type electrode 130.

In the production method according to the present disclosure, etching for exposing the n-type AlGaN layer 30 in the third step is performed after etching for forming the street region in the second step. Conventionally, it is generally the case that etching for forming a street region is performed after etching for exposing an n-type semiconductor layer has been performed. However, by performing etching for exposing an n-type semiconductor layer after etching for forming a street region has been performed, it is possible to form an exposed surface of the substrate 10 and to form the angle θs with respect a horizontal line of an interface between the substrate 10 and the buffer layer 20. Moreover, an angle formed by the interface between the substrate 10 and the buffer layer 20 and an inclined surface of the buffer layer 20 (i.e., angle θb) is smaller than is conventionally the case. This makes it less likely that peeling, cracking, or the like of a subsequently described protective film will occur.

### Fourth Step

Formation of a protective film is performed in a region exclusive of at least central sections (bonding regions) of upper surfaces of the p-side electrode and the n-type electrode. Moreover, in order to avoid staining of an electrode surface or protective film surface due to evaporation and redeposition of the protective film caused by laser irradiation, it is preferable that the protective film is not present and that the sapphire substrate is exposed at a position of laser irradiation by a laser scriber.

A fourth step that is a step of forming a protective film is taken to be a step of forming a protective film on at least the respective side surfaces of the p-type AlGaN layer, the light-emitting layer, the n-type AlGaN layer, and the buffer layer that have been formed as a result of etching in the second step and the third step described above and also on at least the inclined section in the street region of the substrate. The thickness of the protective film can be set as 0.2 μm to 3 μm. The protective film is preferably SiO₂, SiN, SiON, or a combination thereof.

Finally, it is preferable that contact annealing is performed using an infrared lamp annealing heating device and that a laser scriber is subsequently used to separate individual elements with a square shape having a chip size of not less than 500 μm×500 μm and not more than 1,500 μm×1,500 μm. The thickness of the sapphire substrate after element separation is preferably not less than 100 μm and not more than 600 μm.

The following provides a more detailed description of the present disclosure using examples. However, the present disclosure is not in any way limited by the following examples.

### Example 1

### Experimental Example 1

A sapphire substrate (diameter: 2 inches; thickness: 430 μm; orientation (0001); m-axis direction off-angle θ: 0.5°) was prepared, and an AlN buffer layer having a central thickness of 600 nm was grown on the sapphire substrate by MOCVD with the growth temperature set as 1200° C. Thereafter, 4 hours of heating was performed at 1650° C. in a nitrogen gas atmosphere using a heat treatment furnace.

The full width at half maximum of a (10-12) X-ray rocking curve measured by an X-ray diffractometer (D8 DISCOVER AUTOWAFS produced by Bruker AXS; Cu Kα1 line) with respect to the AlN layer of the AlN template substrate was 288 seconds, and thus was 300 seconds or less.

After the AlN template substrate had been obtained, a first buffer layer of 30 nm in thickness that was formed of undoped Al_{0.40}Ga_{0.60}N was formed on the AlN template substrate by MOCVD with the growth temperature set as 1200° C. Next, a second buffer layer of 1,000 nm in thickness that was formed of undoped Al_{0.25}Ga_{0.75}N was formed. The total thickness of the undoped first buffer layer and second buffer layer measured from a cross-sectional SEM image was 1,030 nm.

Next, an n-type semiconductor layer of 2,400 nm in thickness that was formed of Si-doped Al_{0.25}Ga_{0.75}N was formed on the second buffer layer. In addition, the growth temperature was changed from 1200° C. to 1100° C., and then an n-type guide layer of 25 nm in thickness that was formed of Si-doped Al_{0.25}Ga_{0.75}N was formed on the n-type semiconductor layer.

Next, a light-emitting layer having a quantum well structure was formed through three repetitions of formation of a barrier layer of 12 nm in thickness that was formed of Si-doped Al_{0.25}Ga_{0.75}N and a well layer of 2.4 nm in thickness that was formed of undoped Al_{0.10}Ga_{0.90}N.

Thereafter, an i-type guide layer of 3 nm in thickness that was formed of undoped Al_{0.25}Ga_{0.75}N was formed on the light-emitting layer (on the third well layer). Supply of group III source gas was subsequently suspended while continuing supply of group V source gas. Nitrogen gas as a carrier gas was suspended, and the carrier gas was changed to hydrogen gas. At 1 minute after the start of supply of hydrogen gas, supply of group III source gas was started, and a p-type electron blocking layer of 22 nm in thickness that was formed of Mg-doped Al_{0.4}Ga_{0.6}N was formed. Next, a p-type cladding layer of 64 nm in thickness that was formed of Mg-doped Al_{0.22}Ga_{0.78}N was formed, and then a p-type contact layer (p-type GaN contact layer) of 4 nm in thickness that was formed of Mg-doped GaN was formed. In accompaniment to the change of carrier gas described above, the i-type guide layer underwent volatilization and decomposition of a Ga component and thereby changed to an i-type guide layer of 1.0 nm in thickness that had an Al composition ratio of roughly 1.

A CVD apparatus was used to form an SiO₂ layer over the entirety of the p-type contact layer. This SiO₂ layer fulfills a role as a mask during RIE.

Mask pattern formation by a resist was used with respect to the SiO₂ layer on the p-type contact layer, the SiO₂ layer in a street region (street width: 100 μm) having a belt shape including a planned separation line by subsequent laser scribing was removed using buffered hydrofluoric acid, and then the resist was also removed. An RIE apparatus was used to perform 16 minutes of etching using Cl₂ gas and BCl₃ gas as etching gases. As a result, group III nitride layers in the street region that were not covered by the SiO₂ layer were each etched, thereby exposing the sapphire substrate in the street region.

Next, mask pattern formation by a resist was used to retain the SiO₂ layer on a region (light-emission region) of the p-type semiconductor layers (p-type contact layer, p-type cladding layer, and p-type electron blocking layer) and the light-emitting layer that was to be retained and to remove the SiO₂ other than in that region using buffered hydrofluoric acid, and then the resist was also removed. RIE was used to perform 9 minutes and 30 seconds of etching using Cl₂ gas and SiCl₄ gas as etching gases so as to expose an n-type semiconductor layer in a range that was not covered by the SiO₂ layer. The thickness from an interface between the AlN buffer layer and the first buffer layer to the surface of the exposed n-type semiconductor layer was measured from a cross-sectional SEM image and was determined to be 3,000 nm.

In exposure of the n-type semiconductor layer, the sapphire substrate in the street region that had been exposed during the street formation step was subjected to etching for a second time. Thereafter, the SiO₂ layer (mask) on the p-type contact layer was removed using buffered hydrofluoric acid.

Next, a Ni layer of 7 nm in thickness and a Rh layer of 50 nm in thickness were formed on the p-type contact layer so as to form a reflective electrode as a p-side electrode.

In addition, a Ti layer of 20 nm in thickness and an Al layer of 150 nm in thickness were formed on part of the exposed n-type semiconductor layer so as to form an n-type electrode.

Stacking of the p-side electrode and the n-type electrode was performed by sputtering. Formation of electrode patterns of the p-side electrode and the n-type electrode was performed by a lift-off method using a resist.

Moreover, an infrared lamp annealing heating device was used to perform 10 minutes of contact annealing at 550° C. Next, a protective film formed of SiO₂ with a target thickness of 1 μm was formed over the entire surface with the exception of the planned separation line by laser scribing and central sections (bonding regions) of upper surfaces of the p-side electrode and the n-type electrode. Thereafter, individual elements having a square shape with a chip size of 1,000 μm×1,000 μm were separated using a laser scriber to produce an ultraviolet light-emitting element (hereinafter, also referred to as a light-emitting element) according to Example 1. A side surface of the sapphire substrate was perpendicular to the main surface, and the thickness of the sapphire substrate after element separation was 430 μm.

### Example 2

A light-emitting element according to Example 2 was obtained in the same way as in Example 1 with the exception that the thickness of the second buffer layer was changed to 250 nm. The total thickness of the undoped first buffer layer and second buffer layer measured from a cross-sectional SEM image was 280 nm. The thickness from an interface between the AlN buffer layer and the first buffer layer to the surface of the exposed n-type semiconductor layer was measured from a cross-sectional SEM image and was determined to be 2,050 nm.

### Comparative Example

The following refers to FIGS. 4A to 4C to illustrate process diagrams for a case in which a similar light-emitting element is produced by a conventional production method. First, semiconductor layers were epitaxially grown on a sapphire substrate to form a light-emitting element (FIG. 4A). This step is the same as the first step in the embodiment.

Next, an SiO₂ layer was formed over the entirety of a p-type contact layer 70 using a CVD apparatus, and then mask pattern formation by a resist was used to retain the SiO₂ layer on the p-type contact layer 70 in a region (light-emission region) where p-type semiconductor layers (p-type contact layer 70, p-type cladding layer 60, and p-type AlGaN layer 50) and a light-emitting layer 40 were to be retained and to remove the SiO₂ layer other than in that region by etching. Thereafter, an RIE apparatus was used to expose an n-type AlGaN layer 30 in a range that was not covered by the SiO₂ layer as illustrated in FIG. 4B.

After part of the n-type semiconductor layer had been exposed in this manner, a street formation step was performed. In the street formation step, since the SiO₂ layer other than in the light-emission region had already been removed in the step of exposing the n-type semiconductor layer, an SiO₂ layer was formed once again such as to cover a region other than the street region, inclusive of the exposed upper surface of the n-type semiconductor layer. This SiO₂ layer was used as a mask during RIE in order to etch each group III nitride layer in the street region that was not covered by the SiO₂ layer and thereby expose the sapphire substrate in the street region with an etching time in the street formation step that was changed from 16 minutes to 12 minutes. A light-emitting element according to a Comparative Example was obtained in the same way as in Example 1 with the exception that the order of the street formation step and the step of exposing the n-type semiconductor layer was reversed and that the etching time in the street formation step was changed. The light-emitting element according to the Comparative Example differs from Example 1 and Example 2 in terms that the sapphire substrate in the street region is subjected to etching just once in the street formation step. As illustrated in FIG. 4C, an inclined section is not formed in the sapphire substrate in the street region in this case.

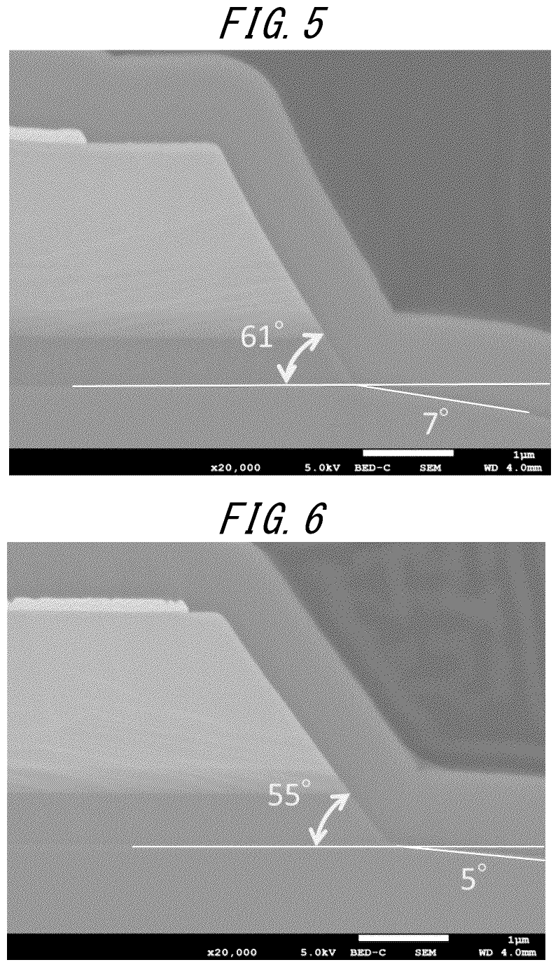

Cross-sectional images of Example 1 and Example 2 are respectively presented in FIG. 5 and FIG. 6. In these drawings, a horizontal line of an interface between the sapphire substrate and the AlN buffer layer on the AlN template substrate, a value of an angle (θs) between the horizontal line and the inclined section of the sapphire substrate, and a value of an angle (θb) between the horizontal line and the AlN buffer layer are recorded. In Example 1, θs was 7° and θb was 61°. In Example 2, θs was 5° and θb was 55°. In each of Examples 1 and 2, the inclined section of the sapphire substrate is a section up to 2 μm in a horizontal rightward direction from a contact point of the sapphire substrate and the side surface of the AlN layer in the cross-sectional SEM image. A section beyond 2 μm in the horizontal rightward direction is flat. In contrast, in the Comparative Example, the angle (θs) between the horizontal line and an inclined section of the sapphire substrate was zero (i.e., an inclined section was not formed). Moreover, the angle (θb) between a boundary line and the AlN buffer layer was 82°.

Table 1 shows θs, θb, θs+ (180°−θb), and evaluation of close adherence between a protective film and a semiconductor layer for Examples 1 and 2 and the Comparative Example. Note that θs+ (180°−θb) is the angle at which the protective film contacts with the semiconductor layer at a surface where the sapphire substrate and the side surface of the AlN layer come into contact. The value of θs+ (180°−θb) was 126° in Example 1 and 130° in Example 2. As a result of the value of θs+ (180°−θb) being sufficiently large, cracks or voids between the semiconductor layer and the protective film were not observed, and close adherence was sufficient. In contrast, in the Comparative Example in which the value of θs+ (180°−θb) was 98° (i.e., close to a right angle), there were instances in which voids or cracks were observed in part of a section where the protective film was in contact.

TABLE 1

| | | | θs + | Close |
|---|---|---|---|---|
| | θs | θb | (180° − θb) | adherence |
| Example 1 | 7° | 61° | 126° | Good |
| Example 2 | 5° | 55° | 130° | Good |
| Comparative | 0° | 82° | 98° | Poor |
| Example | | | | |

The results set forth above demonstrate that it was possible to obtain a semiconductor element with which peeling, cracking, or the like of a protective film is unlikely to occur by controlling the size of the angles θs and θb and by setting the size of θs+ (180°−θb) as 120° or more.

1. A light-emitting element of a flip chip type comprising:
a buffer layer formed on a main surface of a substrate;
an n-type AlGaN layer formed on the buffer layer; and
a light-emitting layer and a p-type AlGaN layer formed in order on at least part of the n-type AlGaN layer, wherein
an exposed surface of the substrate is present at an end section on the main surface of the substrate, and
in a cross-section of the light-emitting element, the exposed surface has an inclined section that is inclined at an acute angle θs of 45° or less relative to a horizontal line of an interface between the substrate and the buffer layer.

2. The light-emitting element according to claim 1, wherein the acute angle θs satisfies 2°<θs<30°.

3. The light-emitting element according to claim 1, wherein
when an angle formed in the buffer layer by the interface and a side surface of the buffer layer is taken to be θb,
θs<30°≤θb≤75°, and
θs+(180°−θb) is 120° or more.

4. The light-emitting element according to claim 1, wherein an end section where an exposed surface of the n-type AlGaN layer and a side surface of the n-type AlGaN layer meet is formed with a rounded shape.

5. The light-emitting element according to claim 1, wherein
the substrate includes a sapphire substrate, and
the buffer layer includes at least an undoped AlN buffer layer.

6. The light-emitting element according to claim 1, further comprising a protective film that covers at least respective side surfaces of the p-type AlGaN layer, the light-emitting layer, the n-type AlGaN layer, and the buffer layer and that covers at least the inclined section.

7. A method of producing a light-emitting element comprising:
a first step including a step of forming a buffer layer on a main surface of a substrate, a step of forming an n-type AlGaN layer on the buffer layer, and a step of forming a light-emitting layer and a p-type AlGaN layer in order on the n-type AlGaN layer;
a second step of etching at least part of the p-type AlGaN layer, the light-emitting layer, the n-type AlGaN layer, and the buffer layer up to the substrate to form a street region at the substrate; and
a third step of exposing part of the n-type AlGaN layer by etching the p-type AlGaN layer and the light-emitting layer once again after the second step, wherein
in a cross-section after the third step, the street region of the substrate has an inclined section that is inclined at an acute angle θs of 45° or less relative to a horizontal line of an interface between the substrate and the buffer layer.

8. The method of producing a light-emitting element according to claim 7, further comprising a fourth step of forming a protective film on at least respective side surfaces of the p-type AlGaN layer, the light-emitting layer, the n-type AlGaN layer, and the buffer layer that have been formed through etching in the second step and the third step and forming a protective film on at least the inclined section of the street region of the substrate.
